(19) United States
(12) Patent Application Publication
(10) Pub. No.: US 2025/0191938 A1
(43) Pub. Date: Jun. 12, 2025

(54) Overmolding Structures in Glass

(71) Applicant: 3D Glass Solutions, Inc., Albuquerque, NM (US)

(72) Inventors: Jeb H. Flemming, Albuquerque, NM (US); Mark Popovich, Coto de Caza, CA (US)

(21) Appl. No.: 18/845,967

(22) PCT Filed: Mar. 15, 2023
(86) PCT No.: PCT/US2023/064364

§ 371 Date: Sep. 11, 2024

Related U.S. Application Data
(60) Provisional application No. 63/321,421, filed on Mar. 18, 2022.

(51) Int. Cl. H01L 21/56; H01L 21/67; H01L 23/31

(52) U.S. Cl. CPC H01L 21/56; H01L 21/67126; H01L 23/3107

(57) ABSTRACT

An apparatus of one or more electronic devices in or on a photodefinable glass substrate includes: the photodefinable glass substrate; the one or more electronic devices disposed in or on the photodefinable glass substrate; one or more overmolding openings in the photodefinable glass substrate; and a layer of overmolding material filling the one or more overmolding openings and covering at least a portion of the one or more electronic devices.

### CROSS-REFERENCE TO RELATED APPLICATIONS

This application claims priority to U.S. Provisional Application Ser. No. 63/321,421, filed Mar. 18, 2022, the entire contents of which are incorporated herein by reference.

### STATEMENT OF FEDERALLY FUNDED RESEARCH

None.

### TECHNICAL FIELD OF THE INVENTION

The present invention relates to a method of encapsulating components and related apparatuses. More particularly, the present invention relates to overmolding electronic devices on glass substrates.

### BACKGROUND OF THE INVENTION

Without limiting the scope of the invention, the background of the invention is described in connection with RF and electronic circuits.

There is an increasing demand for overmolded electronics packages driven by wearable devices, small-form-factor devices, device-to-device communications, RF communications, and many other applications. Overmolding packaging techniques provide enhanced mechanical strength, reduced electrostatic discharge (ESD) damage, reduced packaging sizes, and protection against moisture, dust, dirt, and vibration. Overmolding also seals connectors, overmolding grommets (also referred to herein as “overmolding openings”), and strain reliefs. The primary reason for the overmolding openings is to enhance the adhesion of the overmolding material to a substrate. Overmolding technology can thus protect integrated circuit dies, passive electronic components or systems-in-a-package (SiPs), among other items.

Overmolding can be executed by a variety of methods and materials to encapsulate RF and electronic circuits. These methods and materials include low-pressure molding (LPM) processes and liquid silicone rubber (LSR) molding processes. An LPM process can include either polyamide or polyolefin (hot-melt) materials and is typically used to encapsulate and environmentally protect electronic components. Injection molding of liquid silicone rubber (LSR) is typically used to produce pliable, durable parts in high volume. Overmolding encapsulation is used on a number of substrates including printed circuit boards (PCBs), silicon, sapphire, and other substances.

LSR is a resin that is based on cured silicone with low compression set, high stability, and resistance to extreme temperatures. LSR is ideally suitable for production of parts where high quality is a must. Thermosetting liquid-silicone injection molding requires intensive distributive mixing at a low temperature before being pushed into a heated cavity. Materials that flow easily at elevated temperatures and solidify at lower temperatures are called thermoplastics.

LPM materials used in overmolding for electronics include the group of amorphous thermoplastic polyamides because they have a processing temperature range of 180 to 240° C. and a viscosity of around 3,000 centipoise. Polyamides have two appropriate characteristics for electronic molding. The first characteristic is the adhesion properties of polyamide. Polyamide is a high performance hot-melt material that mechanically adheres to the substrate. Mechanical adhesion means that there is no chemical reaction with the substrate. To facilitate the necessary adhesion, overmolding openings have been used to anchor the overmolding material to the substrate. These overmolding openings are created by etching or milling a shaped hole, via, trench, or other structure into the substrate to allow the molded material to flow into the opening. The molded material then solidifies around the electronic components, wiring, bonding pads, or adhesion structures. An overmolding opening is typically filled in a few seconds but a typical full molding cycle lasts 20 to 45 seconds. Some solutions for creating openings in overmolded packages include laser cutting and mechanical drilling. These solutions may be augmented by using a molding enclosure (e.g., a mold chase) that creates a surface vacancy (e.g., edge beveling) or a removable insert. Some components may require precise opening tolerances, such as an opening above an optical sensor. In consumer electronics, it is highly desirable to improve and expand the use of overmolding electronics packaging while reducing the difficulties with those overmolding processes. Unfortunately, the current technology processes for mechanical adhesion have not been translatable to glass substrates as the adhesion between the glass and overmolding material is not sufficient to survive handling and packaging.

### SUMMARY OF THE INVENTION

In one embodiment, the present invention includes a method for overmolding one or more electronic devices in or on a photodefinable glass substrate, the method including providing the photodefinable glass substrate comprising the one or more electronic devices; forming one or more overmolding openings in the photodefinable glass substrate; and applying an overmolding material to fill the one or more overmolding openings and to cover at least a portion of the one or more electronic devices. In one aspect, the photodefinable glass substrate includes silica, lithium oxide, aluminum oxide, and cerium oxide. In another aspect, the method further includes masking a design layout comprising one or more overmolding structures to form the one or more overmolding openings; exposing at least one portion of the photosensitive glass substrate to an activating energy source; heating the photosensitive glass substrate for at least ten minutes above a glass transition temperature thereof; and cooling the photosensitive glass substrate to transform at least part of the exposed glass to a crystalline material to form a glass-crystalline substrate. In another aspect, the step of forming the one or more overmolding openings is performed by etching the glass-crystalline structure with an etchant. In another aspect, an anisotropic-etch ratio of an exposed portion to an unexposed portion is at least 30:1. In another aspect, each of the one or more overmolding openings comprises a top aperture and an interior, and wherein at least a portion of the interior is wider than the top aperture. In another aspect, the overmolding material comprises a liquid silicone rubber, a polyolefin, or an amorphous thermoplastic polyamide. In another aspect, the step of applying the overmolding material is performed using a low-pressure molding process or a liquid silicone rubber process to achieve the flowability and forming of the overmold. In another aspect, each overmolding opening is a blind opening or a through opening. In another aspect, the one or more electronic devices comprise an integrated-circuit die; one or more passive electronic components; one or more lumped circuit elements including a resistor, an inductor, or a capacitor; or a system-in-a-package.

Another embodiment includes an apparatus of one or more electronic devices in or on a photodefinable glass substrate, the apparatus including: the photodefinable glass substrate; the one or more electronic devices disposed in or on the photodefinable glass substrate; one or more overmolding openings in the photodefinable glass substrate; and a layer of overmolding material filling the one or more overmolding openings and covering at least a portion of the one or more electronic devices. In one aspect, each of the one or more overmolding openings comprises a top aperture and an interior, and wherein at least a portion of the interior is wider than the top aperture. In another aspect, the photodefinable glass substrate comprises silica, lithium oxide, aluminum oxide, and cerium oxide. In another aspect, the overmolding material comprises a liquid silicone rubber, a polyolefin, or an amorphous thermoplastic polyamide. In another aspect, the step of applying the overmolding material is performed using a low-pressure molding process or a liquid silicone rubber process. In another aspect, the one or more overmolding openings are formed by masking a design layout comprising one or more overmolding structures to form the one or more overmolding openings; exposing at least one portion of the photosensitive glass substrate to an activating energy source; heating the photosensitive glass substrate for at least ten minutes above a glass transition temperature thereof; and cooling the photosensitive glass substrate to transform at least part of the exposed glass to a crystalline material to form a glass-crystalline substrate. In another aspect, the step of forming the one or more overmolding openings is performed by etching the glass-crystalline structure with an etchant. In another aspect, an anisotropic-etch ratio of an exposed portion to an unexposed portion is at least 30:1. In another aspect, each overmolding opening is a blind opening or a through opening. In another aspect, the one or more electronic devices comprise an integrated-circuit die; one or more passive electronic components including a resistor, an inductor, or a capacitor; one or more lumped circuit elements including a resistor, an inductor, or a capacitor; or a system-in-a-package.

Another embodiment includes an apparatus of one or more electronic devices in or on a photodefinable glass substrate, the apparatus including, the photodefinable glass substrate, the one or more electronic devices disposed in or on the photodefinable glass substrate, one or more overmolding openings in the photodefinable glass substrate, and a layer of overmolding material filling the one or more overmolding openings and covering at least a portion of the one or more electronic devices, made by a method including masking a design layout comprising one or more overmolding structures to form the one or more overmolding openings; exposing at least one portion of the photosensitive glass substrate to an activating energy source; heating the photosensitive glass substrate for at least ten minutes above a glass transition temperature thereof; and cooling the photosensitive glass substrate to transform at least part of the exposed glass to a crystalline material to form a glass-crystalline substrate. In one aspect, the step of applying the overmolding material is performed using a low-pressure molding process or a liquid silicone rubber process. In another aspect, the step of forming the one or more overmolding openings is performed by etching the glass-crystalline structure with an etchant. In another aspect, an anisotropic-etch ratio of an exposed portion to an unexposed portion is at least 30:1.

### BRIEF DESCRIPTION OF THE DRAWINGS

For a more complete understanding of the features and advantages of the present invention, reference is now made to the detailed description of the invention along with the accompanying figures and in which:

FIG. 1 shows a cross-section with exemplary overmolding openings in a photodefinable glass substrate;

FIG. 2 shows an overmolded system-in-a-package (SiP);

FIG. 3 shows a cross-section of an overmolding opening in a copper-metalized substrate;

FIG. 4 shows a cross-section of a photodefinable glass substrate with surface-mounted electronic devices and filled blind and through-hole overmolded openings;

FIG. 5 shows a cross-section of a surface-mounted wire-bonded die covered by an overmolding layer affixed by filled overmolding openings;

FIG. 6 shows a top view of an SiP with overmolding openings in the corners; and

FIG. 7 shows a flowchart for a method embodiment of the invention.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

The devices of the present invention can be used for devices and arrays in glass ceramic substrates for electronic, microwave, and radiofrequency in general. This invention creates a cost-effective glass ceramic inductive individual or array devices. It is possible, using glass ceramic substrates, to form inductive individual or array devices through the processing of both the vertical as well as horizontal planes either separately or at the same time. Using glass ceramic substrates circulator/isolator devices can be made and used in a wide variety of telecommunications and other platforms. The novel circulator/isolator glass ceramic devices can be made as stand-alone devices to add to other devices, can be built into a substrate directly and then connected to other electronic components using vias, wire or ball bonding, etc.

In one embodiment, the present invention is an RF circulator/isolator built for an integrated passive device (IPD) that has a decreased size versus currently available options. The present invention can be made by optimization an Iron Core Material in a Test Vehicle. The test vehicle can include, e.g., one or more types of glass made and formulated as described herein and obtained from, e.g., 3DGS, USA, with methods and parts for improved by iron core filling. First, a standard cavity depth will be used to ensure consistent measurement. Next, components that are formed, added, or connected to form a circuit are connected to the circulator/isolator and are then evaluated as testing proceeds and specific volumes are necessary for accurate calculations.

An overmolded apparatus can be built-in, on, our about a glass-ceramic (APEX® glass-ceramic) as a novel packaging and substrate material for semiconductors, RF electronics, microwave electronics, and optical imaging devices. APEX® glass-ceramic is processed using first-generation semiconductor equipment in a simple three-step process and the final material can be fashioned into either glass, ceramic, or a material containing regions of both glass and ceramic. The APEX® glass ceramic possesses several benefits over current materials, including easily fabricated high density vias, demonstrated microfluidic capability, micro-lens or micro-lens array capability, a high Young's modulus for stiffer packages, halogen-free manufacturing, and economical manufacturing. Photodefinable glasses have several advantages for the fabrication of a wide variety of microsystems components. Microstructures have been produced relatively inexpensively with these glasses using conventional semiconductor processing equipment. In general, glasses have high temperature stability, good mechanical and electrical properties, and better chemical resistance than plastics and many metals. One example of a glass ceramic includes, for example, silicon oxide (SiO₂) of 75 to 85% by weight, lithium oxide (Li₂O) of 7 to 11% by weight, aluminum oxide (Al₂O₃) of 3 to 6% by weight, sodium oxide (Na₂O) of 1 to 2% by weight, 0.2% to 0.5% by weight of either antimony trioxide (Sb₂O₃), arsenic oxide (As₂O₃) or silver oxide (Ag₂O) of 0.05 to 0.15% by weight, and cerium oxide (CeO₂) of 0.01 to 0.04% by weight. As used herein the terms “APEX® glass ceramic,” “APEX® glass,” or simply “APEX®” are used to denote one embodiment of the glass-ceramic composition for making an apparatus with one or more electronic devices on or in a photodefinable glass substrate that has blind or through overmolding openings etched or machined into the photodefinable glass substrate, where the electronic circuit and overmolding openings are filled by the use of a standard overmolding material and process.

Any exposed portion of the photodefinable glass substrate in the form of an overmolding opening structure is transformed into a crystalline material by heating the glass substrate to a temperature near the glass transformation temperature. When etching the glass substrate in an etchant such as hydrofluoric (HF) acid, the anisotropic-etch ratio of the exposed portion to the unexposed portion is at least 30:1 when the glass is exposed to a broad spectrum mid-ultraviolet (about 308-312 nm) flood lamp. The exposed glass is then baked typically in a two-step process. First, the exposed glass is heated between 420° C. and 520° C. for between 10 minutes to 2 hours, to coalesce silver ions into silver nanoparticles and second, the exposed glass is heated between 520° C. and 620° C. for between 10 minutes and 2 hours, allowing the lithium oxide to form around the silver nanoparticles. The glass plate is then etched. The glass substrate is etched in an etchant of HF solution, typically 5% to 10% by volume, wherein the etch ratio of an exposed portion to that of an unexposed portion is at least 30:1, thus delineating one or more overmolding openings. The overmolding openings are then filled using a standard overmolding process and material.

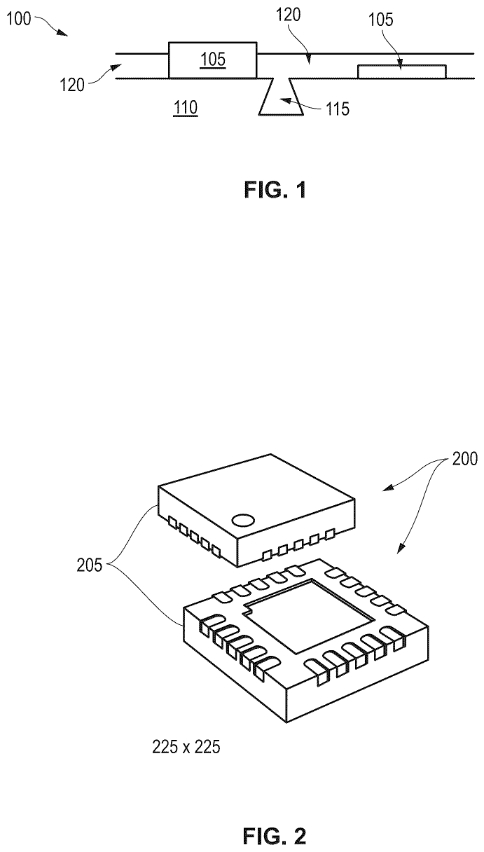

FIG. 1 shows a cross-section of an embodiment with exemplary overmolding openings in a photodefinable glass substrate. The apparatus 100 has one or more electronic devices 105 disposed in or on the photodefinable glass substrate 110. There is an exemplary overmolding opening 115 in the photodefinable glass substrate 110. The layer of overmolding material 120 fills the overmolding opening 115 and covers at least a portion of each of the electronic devices 105. In an aspect of the embodiment, the overmolding opening 115 includes a top aperture and an interior, and at least a portion of the interior of the overmolding opening 115 is wider than the top aperture of the overmolding opening 115. In another aspect, the photodefinable glass substrate 110 includes silica, lithium oxide, aluminum oxide, and cerium oxide. In another aspect, the overmolding material 120 comprises a liquid silicone rubber, a polyolefin, or an amorphous thermoplastic polyamide. In another aspect, the overmolding material is performed using a low-pressure molding process or a liquid silicone rubber process. In another aspect, the one or more overmolding openings are formed by masking a design layout comprising one or more overmolding structures to form the one or more overmolding openings; exposing at least one portion of the photosensitive glass substrate to an activating energy source; heating the photosensitive glass substrate for at least ten minutes above a glass transition temperature thereof, and cooling the photosensitive glass substrate to transform at least part of the exposed glass to a crystalline material to form a glass-crystalline substrate. In another aspect, the step of forming the overmolding openings 115 is performed by etching the glass-crystalline structure with an etchant. In another aspect, an anisotropic-etch ratio of an exposed portion to an unexposed portion is at least 30:1. In another aspect, the one or more electronic devices 105 comprise an integrated-circuit die; one or more passive electronic components including a resistor, an inductor, or a capacitor; one or more lumped circuit elements including a resistor, an inductor, or a capacitor; or a system-in-a-package.

FIG. 2 shows an overmolded system-in-a-package (SiP). The SiP 200 is shown with the overmolding layer 205. [THIS IS NOT SHOWN]

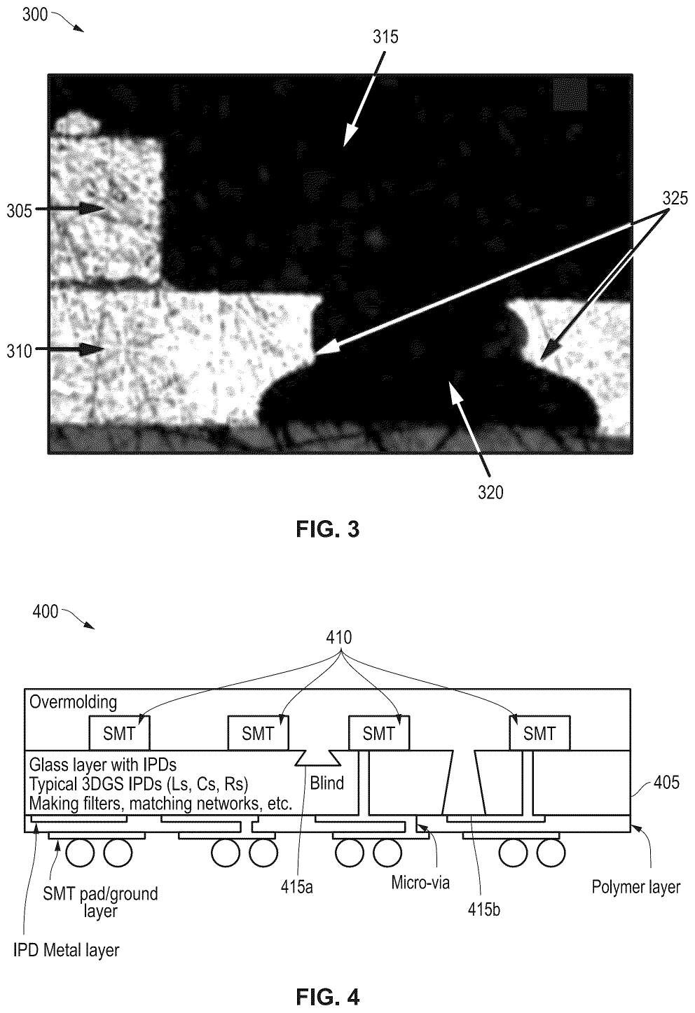

FIG. 3 shows a cross-section of an overmolding opening in a copper-metalized substrate. The apparatus 300 is shown with the integrated circuit die 305 on the copper-metalized substrate 310. The overmolding material 315 covers the integrated circuit die 305 and fills the overmolding opening 320, which has the etched lock feature 325, where portions of the interior of the overmolding opening 320 are wider than the top aperture of the overmolding opening 320 and serve to lock the overmolding material to the copper-metalized substrate 310.

FIG. 4 shows a cross-section of an apparatus 400 with the photodefinable glass substrate 405 with one or more surface-mounted electronic devices 410 and filled blind and through overmolding openings 415a, b.

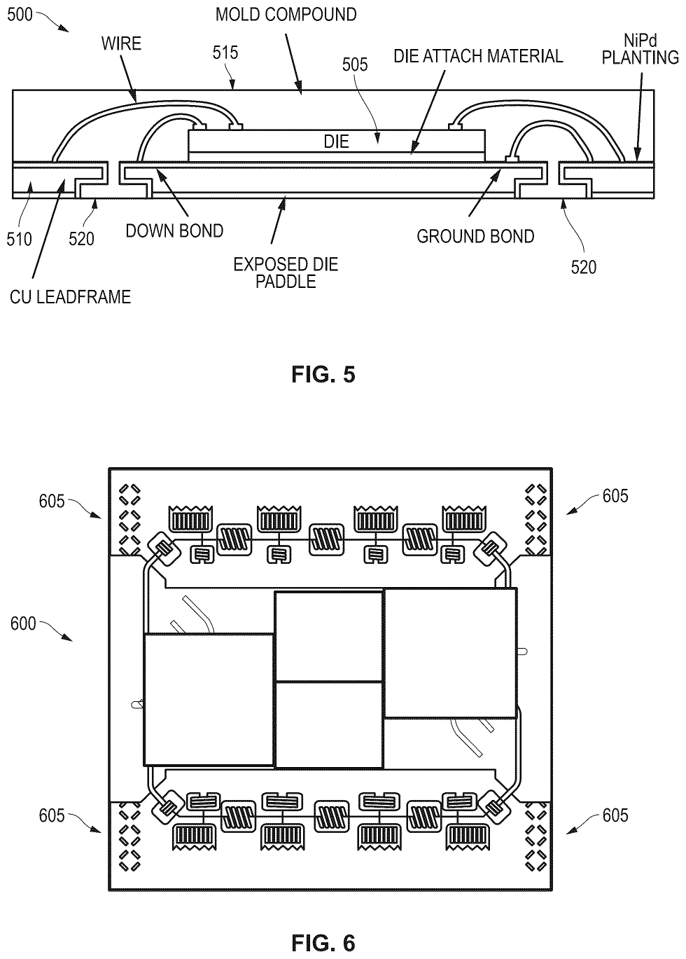

FIG. 5 shows a cross-section of an apparatus 500 with a surface-mounted wire-bonded integrated circuit die 505 on a copper lead frame 510 and covered by the layer 515 of overmolding material affixed by the filled overmolding openings 520.

FIG. 6 shows a top view of an SiP with overmolding openings in the corners. The SiP 600 has the overmolding openings 605.

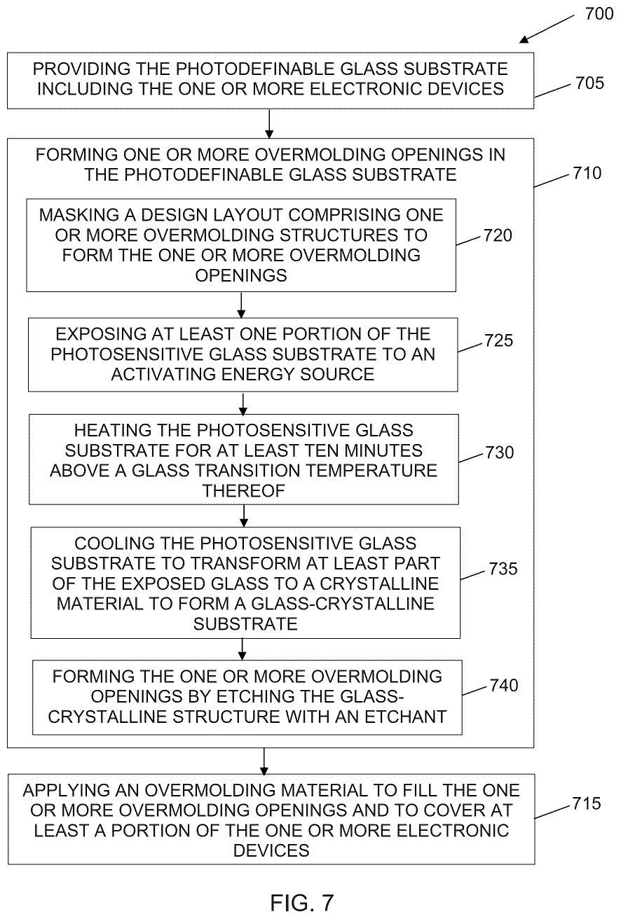

FIG. 7 shows a method embodiment of the invention. The method 700 begins with block 705, providing the photodefinable glass substrate including the one or more electronic devices. Block 710 follows, including forming one or more overmolding openings in the photodefinable glass substrate. The step of applying an overmolding material to fill the one or more overmolding openings and to cover at least a portion of the one or more electronic devices is shown in block 715. An aspect of the embodiment further includes the step of masking a design layout comprising one or more overmolding structures to form the one or more overmolding openings, shown in block 720; exposing at least one portion of the photosensitive glass substrate to an activating energy source, shown in block 725; heating the photosensitive glass substrate for at least ten minutes above a glass transition temperature thereof, shown in block 730; and cooling the photosensitive glass substrate to transform at least part of the exposed glass to a crystalline material to form a glass-crystalline substrate, shown in block 735. Another aspect of the embodiment includes step of forming the one or more overmolding openings by etching the glass-crystalline structure with an etchant, shown in block 740.

In one embodiment, the present invention includes a method for overmolding one or more electronic devices in or on a photodefinable glass substrate, the method consisting essentially of or consisting of: providing the photodefinable glass substrate comprising the one or more electronic devices; forming one or more overmolding openings in the photodefinable glass substrate; and applying an overmolding material to fill the one or more overmolding openings and to cover at least a portion of the one or more electronic devices. In one aspect, the photodefinable glass substrate includes silica, lithium oxide, aluminum oxide, and cerium oxide. In another aspect, the method further includes masking a design layout comprising one or more overmolding structures to form the one or more overmolding openings; exposing at least one portion of the photosensitive glass substrate to an activating energy source; heating the photosensitive glass substrate for at least ten minutes above a glass transition temperature thereof; and cooling the photosensitive glass substrate to transform at least part of the exposed glass to a crystalline material to form a glass-crystalline substrate. In another aspect, the step of forming one or more overmolding openings is performed by etching the glass-crystalline structure with an etchant. In another aspect, an anisotropic-etch ratio of an exposed portion to an unexposed portion is at least 30:1. In another aspect, each of the one or more overmolding openings comprises a top aperture and an interior, and wherein at least a portion of the interior is wider than the top aperture. In another aspect, the overmolding material comprises a liquid silicone rubber, a polyolefin, or an amorphous thermoplastic polyamide. In another aspect, the step of applying the overmolding material is performed using a low-pressure molding process or a liquid silicone rubber process. In another aspect, each overmolding opening is a blind opening or a through opening. In another aspect, the one or more electronic devices comprise an integrated-circuit die; one or more passive electronic components including a resistor, an inductor, or a capacitor; one or more lumped circuit elements including a resistor, an inductor, or a capacitor; or a system-in-a-package.

In another embodiment, the present invention includes an apparatus of one or more electronic devices in or on a photodefinable glass substrate, the apparatus consisting essentially of or consisting of the photodefinable glass substrate; the one or more electronic devices disposed in or on the photodefinable glass substrate; one or more overmolding openings in the photodefinable glass substrate; and a layer of overmolding material filling the one or more overmolding openings and covering at least a portion of the one or more electronic devices. In one aspect, the one or more overmolding openings each comprise a top aperture and an interior, and wherein at least a portion of the interior is wider than the top aperture. In another aspect, the photodefinable glass substrate comprises silica, lithium oxide, aluminum oxide, and cerium oxide. In another aspect, the overmolding material comprises a liquid silicone rubber, a polyolefin, or an amorphous thermoplastic polyamide. In another aspect, the step of applying the overmolding material is performed using a low-pressure molding process or a liquid silicone rubber process. In another aspect, the one or more overmolding openings are formed by masking a design layout comprising one or more overmolding structures to form the one or more overmolding openings; exposing at least one portion of the photosensitive glass substrate to an activating energy source; heating the photosensitive glass substrate for at least ten minutes above a glass transition temperature thereof; and cooling the photosensitive glass substrate to transform at least part of the exposed glass to a crystalline material to form a glass-crystalline substrate. In another aspect, the step of forming one or more overmolding openings is performed by etching the glass-crystalline structure with an etchant. In another aspect, an anisotropic-etch ratio of an exposed portion to an unexposed portion is at least 30:1. In another aspect, each overmolding opening is a blind opening or a through opening. In another aspect, the one or more electronic devices comprise an integrated-circuit die; one or more passive electronic components including a resistor, an inductor, or a capacitor; one or more lumped circuit elements including a resistor, an inductor, or a capacitor; or a system-in-a-package.

In another embodiment, the present invention includes an apparatus of one or more electronic devices in or on a photodefinable glass substrate, the apparatus comprising, the photodefinable glass substrate, the one or more electronic devices disposed in or on the photodefinable glass substrate, one or more overmolding openings in the photodefinable glass substrate, and a layer of overmolding material filling the one or more overmolding openings and covering at least a portion of the one or more electronic devices, made by a method consisting essentially of or consisting of: masking a design layout including one or more overmolding structures to form the one or more overmolding openings; exposing at least one portion of the photosensitive glass substrate to an activating energy source; heating the photosensitive glass substrate for at least ten minutes above a glass transition temperature thereof; and cooling the photosensitive glass substrate to transform at least part of the exposed glass to a crystalline material to form a glass-crystalline substrate. In one aspect, the step of applying the overmolding material is performed using a low-pressure molding process or a liquid silicone rubber process. In another aspect, the step of forming the one or more overmolding openings is performed by etching the glass-crystalline structure with an etchant. In another aspect, an anisotropic-etch ratio of an exposed portion to an unexposed portion is at least 30:1.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), property(ies), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skilled in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

What is claimed is:

1. A method for overmolding one or more electronic devices in or on a photodefinable glass substrate, the method comprising:
providing the photodefinable glass substrate comprising the one or more electronic devices;
forming one or more overmolding openings in the photodefinable glass substrate; and
applying an overmolding material to fill the one or more overmolding openings and to cover at least a portion of the one or more electronic devices.

2. The method of claim 1, wherein the photodefinable glass substrate comprises silica, lithium oxide, aluminum oxide, and cerium oxide.

3. The method of claim 1, further comprising:
masking a design layout comprising one or more overmolding structures to form the one or more overmolding openings;
exposing at least one portion of the photosensitive glass substrate to an activating energy source;
heating the photosensitive glass substrate for at least ten minutes above a glass transition temperature thereof; and
cooling the photosensitive glass substrate to transform at least part of the exposed glass to a crystalline material to form a glass-crystalline substrate.

4. The method of claim 3, wherein the step of forming the one or more overmolding openings is performed by etching the glass-crystalline structure with an etchant.

5. The method of claim 3, wherein an anisotropic-etch ratio of an exposed portion to an unexposed portion is at least 30:1.

6. The method of claim 1, wherein each of the one or more overmolding openings comprises atop aperture and an interior, and wherein at least a portion of the interior is wider than the top aperture.

7. The method of claim 1, wherein the overmolding material comprises a liquid silicone rubber, a polyolefin, or an amorphous thermoplastic polyamide.

8. The method of claim 1, wherein the step of applying the overmolding material is performed using a low-pressure molding process or a liquid silicone rubber process.

9. The method of claim 1, wherein each overmolding opening is a blind opening or a through opening.

10. The method of claim 1, wherein the one or more electronic devices comprise an integrated-circuit die; one or more passive electronic components including a resistor, an inductor, or a capacitor; one or more lumped circuit elements including a resistor, an inductor, or a capacitor; or a system-in-a-package.

11. An apparatus of one or more electronic devices in or on a photodefinable glass substrate, the apparatus comprising:
the photodefinable glass substrate;
the one or more electronic devices disposed in or on the photodefinable glass substrate;
one or more overmolding openings in the photodefinable glass substrate; and
a layer of overmolding material filling the one or more overmolding openings and covering at least a portion of the one or more electronic devices.

12. The apparatus of claim 11, wherein each of the one or more overmolding openings comprises a top aperture and an interior, and wherein at least a portion of the interior is wider than the top aperture.

13. The apparatus of claim 11, wherein the photodefinable glass substrate comprises silica, lithium oxide, aluminum oxide, and cerium oxide.

14. The apparatus of claim 11, wherein the overmolding material comprises a liquid silicone rubber, a polyolefin, or an amorphous thermoplastic polyamide.

15. The apparatus of claim 11, wherein each overmolding opening is a blind opening or a through opening.

16. The apparatus of claim 11, wherein the one or more electronic devices comprise an integrated-circuit die; one or more passive electronic components including a resistor, an inductor, or a capacitor; one or more lumped circuit elements including a resistor, an inductor, or a capacitor; or a system-in-a-package.

17. An apparatus of one or more electronic devices in or on a photodefinable glass substrate, the apparatus comprising, the photodefinable glass substrate, the one or more electronic devices disposed in or on the photodefinable glass substrate, one or more overmolding openings in the photodefinable glass substrate, and a layer of overmolding material filling the one or more overmolding openings and covering at least a portion of the one or more electronic devices, made by a method comprising:
masking a design layout comprising one or more overmolding structures to form the one or more overmolding openings;
exposing at least one portion of the photosensitive glass substrate to an activating energy source;
heating the photosensitive glass substrate for at least ten minutes above a glass transition temperature thereof, and
cooling the photosensitive glass substrate to transform at least part of the exposed glass to a crystalline material to form a glass-crystalline substrate.

18. The apparatus of claim 17, wherein the step of applying the overmolding material is performed using a low-pressure molding process or a liquid silicone rubber process.

19. The apparatus of claim 17, wherein the step of forming the one or more overmolding openings is performed by etching the glass-crystalline structure with an etchant.

20. The apparatus of claim 17, wherein an anisotropic-etch ratio of an exposed portion to an unexposed portion is at least 30:1.
